(19) United States
(12) Patent Application Publication
(10) Pub. No.: US 2021/0103898 A1
(43) Pub. Date: Apr. 8, 2021

(54) MONITORING EQUIPMENT, MONITORED SYSTEM INCLUDING SUCH EQUIPMENT, AND RELATED MONITORING PROCESS

(71) Applicant: Nicola CARLONI, Forli (IT)

(72) Inventor: Nicola CARLONI, Forli (IT)

(21) Appl. No.: 17/048,084

(22) PCT Filed: Apr. 10, 2019
(86) PCT No.: PCT/IB2019/052962

§ 371 Date: Oct. 15, 2020

(30) Foreign Application Priority Data
Apr. 16, 2018 (IT) 102018000004579

(51) Int. Cl. G06Q 10/00; G06Q 10/10; G06Q 10/08

(52) U.S. Cl. CPC G06Q 10/20; G06Q 10/0875; G06Q 10/1091

(57) ABSTRACT

A monitored system capable of computing the number of complex operations of various typologies is composed of a plurality of simple operations performed by machines of various types. The system uses the reading of the variations in the electrical absorption of the machines associated with the absorption time and the typology of machine.

The present invention relates to an equipment for monitoring a plurality of service provision centers, which offer services to the public by means of machines operated by an operator. The invention also relates to a monitored system comprising such equipment and a relative monitoring process. Service provision centers are remote centers, for example branches of a company.

The invention has been devised with particular reference to centers comprising each a plurality of machines designed to perform predetermined services, such as for example service workshops for vehicle tires, where the operations carried out are of predetermined typologies, and therefore can be considered standardized. The application of the invention to other typologies of centers, such as, for example, mechanical workshops for vehicle repairs, is not excluded.

For the sake of simplicity, but not limited thereto, reference hereinafter will be made to the field of vehicle tire service centers. In the case of small workshops, each is generally owned by the same person who manages it, so there are no monitoring problems.

In the case of a company that manages a chain of branches through employees, there is a gap in the monitoring system to establish whether each operation performed in each service provision center has been computed and therefore monetized.

The company must necessarily place its trust in the manager of each workshop.

Furthermore, although the operations performed to provide the services are the same, the machines that perform them may have different brands, models and sizes, which introduces a significant obstacle to centralized monitoring. On the other hand, the idea of standardizing the machines of each branch could mean a serious investment that outweighs the benefit.

In addition, often a complete service that can be monetized consists of several simple operations of different typologies, thus resulting in a complex operation of difficult automatic recognition for the purpose of calculating the number thereof.

The need for a system for monitoring the number and/or typology of operations performed, which is easy and cost-effective to implement, is therefore felt in the field.

In the patent literature, electronic aids are known for storing certain parameters in the tire sector, however they are unrelated to the solution of the above need.

In particular WO2015/041082 relates to the problem of recycling the tires of demolished cars. This international patent application proposes to collect various data relating to the state of wear of the tires (tread height) by means of cameras and sensors to decide whether to send them to re-use or to disposal.

JP2005138738 relates to the problem of keeping track of the history of the services undergone by a tire. The data stored by the system relate to assembly and disassembly and are: tire identification code, vehicle identification code, tire mounting position, vehicle mileage upon assembly/disassembly, typology of assembly or disassembly work performed.

WO2005/006363 relates to a system for detecting damage to the local electricity network through readings of electrical absorption. Readings are carried out by sensors placed at electrical loads in the home.

The general object of the present invention is to partly overcome the problems of the prior art and to provide a monitoring system that meets said need.

In brief, the present invention relates to a monitored system capable of computing the number of complex operations of various typologies composed of a plurality of simple operations performed by machines of various typologies. The system uses the reading of the variations in the electrical absorption of the machines associated with the absorption time and the typology of machine.

According to a first general aspect thereof, the present invention relates to a monitored system for providing services to the public comprising:
a plurality of electric absorption operating machines
a monitoring equipment comprising:
at least one central processing and monitoring apparatus (20);
at least a plurality of devices for reading the electric absorption spectrum (15), each associated with an operating machine (10), and being in data communication with the central processing and monitoring apparatus (20) or being part thereof;

the equipment (25) being programmed to generate a plurality of simple information of a mutually different typology, where:
each “typology of simple information” corresponds to a simple typology of operation
   performed by a predetermined typology of operating machine
   each “simple information” corresponds to a single operation performed of said typology,
   each simple information is recognized by the equipment based on all of the following parameters:
      the typology of operating machine,
      variations in the absorption spectrum with respect to a stand-by absorption of the operating machine,
      based on the duration of the absorption variation,
each simple information includes the time of execution of the operation;
the equipment is programmed to generate a plurality of “complex information” of a mutually different typology, where each typology corresponds to a predetermined concatenation of simple information that identifies a typology of complex operation formed by a plurality of single predetermined operations performed in a predetermined time succession within a predetermined time period, and each complex information generated identifies a complex operation performed by the plurality of operating machines;
the central processing and monitoring apparatus is suitable for displaying the number of complex operations performed and/or a datum dependent thereon.

Advantageously, the absorption variation time is comparable with a reference time that can be used as a threshold to establish whether the change is computable as a simple operation performed or not.

The typologies of simple predetermined operations recognized on the basis of the absorption preferably comprise one or more of the following:

| | Simple operations |
|---|---|
| A | Lifting of a vehicle lifting machine (commonly called |
| | “bridge”) |
| B | Lowering of a vehicle lifting machine |
| C | Rotation of the plate of a machine for disassembling |
| | tires from rims |
| D | Closing of the clamp of a balancing machine |
| E | Opening of the clamp of a balancing machine |
| F | Rotation of the tire on a balancing machine |
| G | Lifting of a machine for checking and/or adjusting |
| | the alignment |
| H | Lowering of a machine for checking and/or adjusting |
| | the alignment |
| J | Actuation of cameras of a machine for checking and/or |
| | adjusting the alignment |

The machines indicated are generally of the common typology, therefore their parts are not further described, being industry standards.

The preferred complex operations that the equipment is programmed to recognize comprise one or more of the following concatenations:

| Complex operations | Execution order |
|---|---|
| Tire replacement | C + C |
| Tire balancing | D + F + E |
| Tire repair | A + C + C + B |
| Tire reversal | A + 4(D + F + E) + B |
| Single wheel replacement | A + 2C + D + F + E + B |
| Complete wheel replacement | A + 8C + 4(D + F + E) + B |
| Alignment check | G + J + H |
| Alignment adjustment | G + J + G + J + H |

wherein

| | Simple operations |
|---|---|
| A | Lifting of a vehicle lifting machine (commonly called |
| | “bridge”) |
| B | Lowering of a vehicle lifting machine |
| C | Rotation of the plate of a machine for |
| | disassembling tires from rims |
| D | Closing of the clamp of a balancing machine |
| E | Opening of the clamp of a balancing machine |
| F | Rotation of the tire on a balancing machine |
| G | Lifting of a machine for checking and/or adjusting |
| | the alignment |
| H | Lowering of a machine for checking and/or adjusting |
| | the alignment. |
| J | Actuation of cameras of a machine for checking and/or |
| | adjusting the alignment |

According to a general preferred feature of the invention, each spectrum reading device is suitable for being interposed between an existing machine and an electric power supply network, in particular each device comprises:
at least one electrical supply socket adapted to be connected to and disconnected from at least one electric machine to be monitored and to electrically power it,
at least one connection of the device to an external power supply network to draw electricity,
at least one sensor for measuring the electric current absorbed by the powered machine (and a possible absorption time detection device);
data transmission means.

In this manner, it is advantageously not necessary to replace or adapt the machines present in the centers to be monitored. The equipment may for example be provided as kits where the detection devices each comprise at least a socket and a plug, so as to be interposed between the sockets of the electrical supply network and the supply plugs of the machines, the detection devices preferably form a switchboard.

According to some preferred embodiments, the system comprises:
a plurality of service provision centers (5) remote from each other and from the central processing and monitoring apparatus (20), each center (5) comprising a plurality of operating machines (10) and a relative plurality of spectrum reading devices (15) placed online with the central processing and monitoring apparatus,
the equipment being programmed to compute the complex operations of each center, associating the simple operations with each other only if they belong to the same center.

Said monitored system preferably comprises a plurality of service centers for vehicle tires, where each center comprises at least one of the following typologies of machines, more preferably all, connected to said monitoring equipment:
tire disassembly machine;
vehicle wheel alignment machine;
vehicle lifting machine;
machine for checking and/or adjusting the convergence of vehicle wheels.

According to a second general aspect of the invention, the invention comprises monitoring equipment of the typology indicated for the monitored system described above.

Preferably, said equipment is distinct from said operating machines and can be connected thereto by means of a method for engaging the reading devices between the power supply sockets of said machines and the electrical supply sockets of the electric network.

According to a third general aspect of the invention, the invention relates to a method—calculating the number of individual random operations performed by each machine divided by typologies of operations that can be performed by said machine, where the recognition of each operation is made based on the variations of the electric absorption spectrum of said machine and their duration time;
keeping track of the execution time of each simple operation;
recognizing the execution of various typologies of complex operations composed of a plurality of simple operations by comparison with predetermined reference concatenations composed of simple operations carried out in temporal succession in a predetermined period;
calculating the number of complex operations performed.

Advantageously, it is possible to compute the number of complex operations composed of simple operations performed by a plurality of mutually different machines.

Advantageously, it is also possible to centrally compute the number of complex operations performed in mutually remote service provision centers.

According to some preferred embodiments, it is provided to define parameters of simple reference operations to be compared with the parameters detected to count the simple operations performed, where said parameters include an absorption variation and a time defined as follows:
performing a first predetermined number of individual operations by means of each machine,
defining a reference absorption variation for each operation based on the absorptions detected during said first predetermined number of operations;
setting a completion reference time for each typology of simple operation based on the times detected during said first predetermined number of operations.

Preferably, it is possible to define each reference concatenation as follows:
performing at least one complex test operation isolated from other operations,
storing the temporal succession in which its simple operations take place;
setting a completion time for all its simple operations based on the time required to complete the complex test operation.

Advantageously with this method it is easy to calculate a monetary value by associating a predetermined monetary value with each complex computed operation.

According to some preferred embodiments of the invention, the process comprises the step of providing a plurality of assistance centers for vehicle tires, where the detected operations comprise one or more of the following:

| | Simple operations |
|---|---|
| A | Lifting of a vehicle lifting machine (commonly called |
| | “bridge”) |
| B | Lowering of a vehicle lifting machine |
| C | Rotation of the plate of a machine for disassembling |
| | tires from rims |
| D | Closing of the clamp of a balancing machine |
| E | Opening of the clamp of a balancing machine |
| F | Rotation of the tire on a balancing machine |
| G | Lifting of a machine for checking and/or adjusting |
| | the alignment |
| H | Lowering of a machine for checking and/or adjusting |
| | the alignment |
| J | Actuation of cameras of a machine for checking and/or |
| | adjusting the alignment |

Further characteristics and advantages of the present invention will become clearer from the following detailed description of the preferred embodiments thereof, with reference to the appended drawings and provided by way of indicative and non-limiting example.

In such drawings:

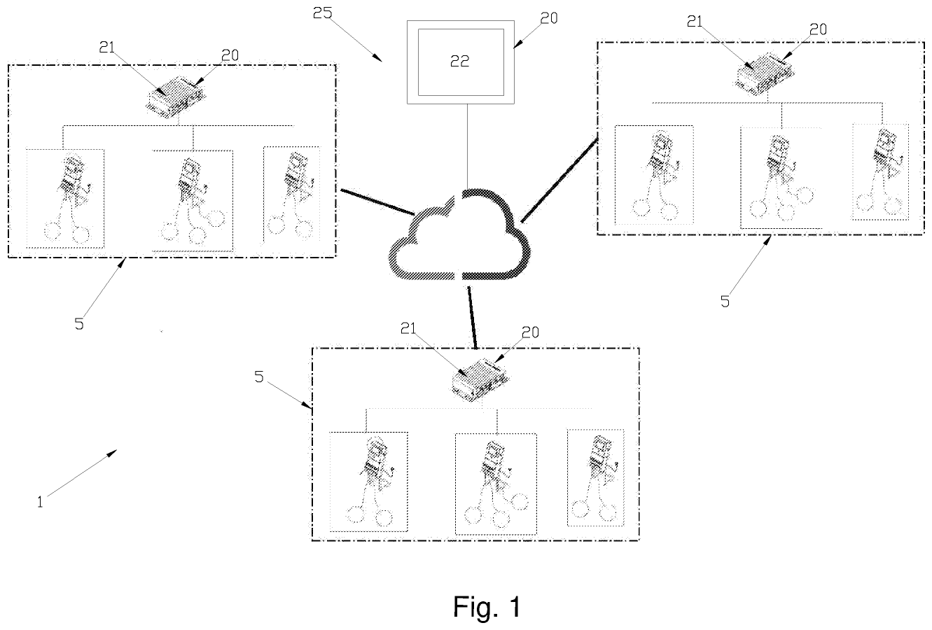

FIG. 1 schematically shows a monitored system according to the present invention;

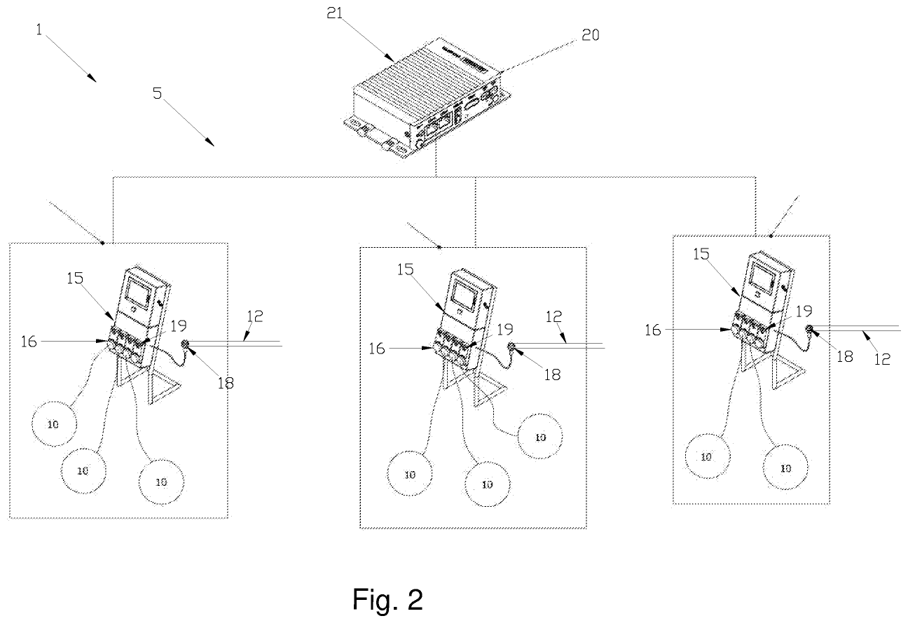

FIG. 2 shows a monitored service provision center;

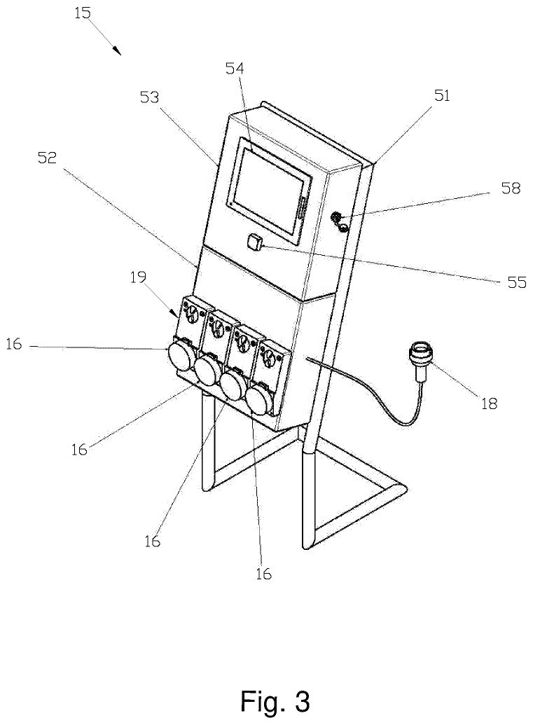

FIG. 3 schematically shows a detection device of the system in FIG. 1;

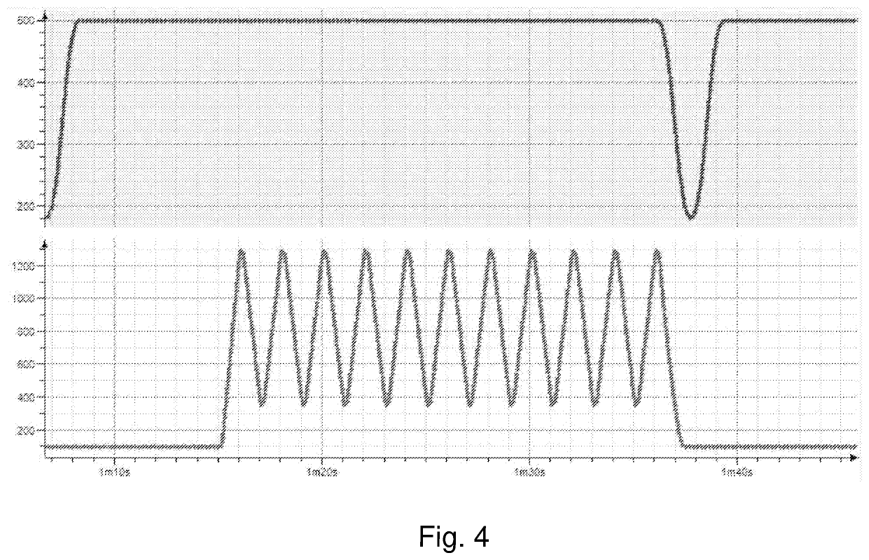

FIG. 4 shows the variation of the electric absorption spectrum of a car lifting machine during the performance of an operation.

With reference to FIG. 1, a monitored system according to the invention is shown as a whole with reference numeral 1.

The system 1 comprises a plurality of centers for the provision of services to the public, preferably but not limited to vehicle tires, also called “branches” for simplicity, and indicated with reference numeral 5.

The centers 5 are in a mutually remote position, each being preferably contained in a relative building, so the order of magnitude of their distance is at least that between two buildings, more frequently at least that between two districts, even more frequently at least that between two inhabited centers.

Each center 5 comprises a plurality of electric absorption operating machines 10, that is, such as to use electric current during their operation. In the case of tires, each branch has at least the following machines 10, or a plurality of them:
at least one machine for disassembling the tires from the rims, and preferably for the reassembly thereof;
at least one vehicle wheel alignment machine;
at least one vehicle lifting machine, generally called “bridge”;
at least one machine for checking and/or adjusting the convergence of vehicle wheels. In general, it comprises a dedicated bridge for lifting the vehicle and an equipment provided with cameras and mirrors for the wheel orientation analysis.

The monitored system 1 further comprises a monitoring equipment indicated as a whole with reference numeral 25, suitable for monitoring the number of operations performed by the machines 10.

The equipment 25 comprises at least one central processing and monitoring apparatus 20 and a plurality of devices for reading the electric absorption spectrum 15.

Each machine 10 is connected to an electrical supply network 12 by means of a device for reading the spectrum of its electric absorption 15. It is possible to provide one or more reading devices 15 for each center 5. The second case is shown in FIG. 2.

The central processing and monitoring apparatus comprises at least one local data processing device 21, for example one for each center 5, placed in data communication with a plurality of reading devices 15 (the variant according to which there is one integrated in each of them is not excluded), and programmed or programmable for recognizing when a machine has performed an operation based on the variation of its electric absorption and to count the operations performed.

The local data processing devices 21 of all the centers are connected in a network with a remote data processing and/or display device 22 capable at least of displaying the processed data relating to all centers 5 in the network, being for example a PC. The network connection is a data exchange connection and takes place, for example, via the internet.

According to a possible alternative, there is a single data processing device 21 which processes the data of all the centers, and which receives the data from all the detection devices of all the centers. In this case, preferably the data processing device 21 coincides with the remote data processing and/or display device 22 and is networked with the detection devices 15.

With reference to FIG. 3, a spectrum reading device 15 according to the invention is shown.

Each spectrum reading device 15 in particular comprises at least one current socket 16 to which a machine 10 can be connected to be powered, for example by means of an electric plug.

Preferably, the device 15 comprises a plurality of sockets 16, each dedicated to a respective machine 10.

It is not excluded that at least one spectrum reading device, preferably all, have a plurality of current sockets 16 of different typologies by amperage and voltage, preferably suitably protected by devices against overload.

The device comprises a second current connection plug 18 for connection to the electrical network 12.

The device 15 is suitable for detecting the electrical absorption of each machine connected thereto, for example by recording its absorption spectrum. To do this, the device 15 comprises at least one absorption sensor 19 for each socket 16.

According to the preferred embodiment shown in FIG. 3, the spectrum reading device 15 comprises a pedestal for the appropriate positioning 51 to which there are fixed a box-typology unit 52 for housing the electric sockets 16 and a box-typology unit 53 for housing a display and signaling device implemented by means of an LCD screen with touch-screen technology 54.

The spectrum reading device is also preferably provided with an RFID reader 55 for the identification of the operator by means of special encoded cards.

Each spectrum reading device 15 is preferably arranged with a variable amount of electrical sockets 16, different by amperage and voltage, at least one per typology, suitably protected by devices against overload to which a plurality of energy-powered operating machines are connected.

The system is powered through a power socket 18 to be connected to the electrical distribution system for easy integration with the pre-existing infrastructures.

The detected data are sent to the central processing and monitoring apparatus 20, in particular to the local processing device 21 or to the remote processing and/or display device 22, through a special wired output port 58 or wireless.

The central processing and/or display device 22 is placed for example in the central office of the company that manages all the branches.

In use, a programming step is performed which includes an initial setting step of the equipment 25. In the setting step, each machine 10 is connected to a relative spectrum reading device 15 and one or more operations are performed with them. During the operations, the spectrum of electric current absorbed at each operation is detected and is used to determine a reference spectrum corresponding to a simple operation to be counted as performed by the machine. Thereafter, during normal use of the set machine, the variation of its electric absorption is detected and the processing device 21 compares it with the reference absorption variation recorded in the setting. Based on the comparison, the processing device calculates the operations performed by the machine.

This process is repeated for each machine of the system 1, whereby the processing device 21 or 22 is able to have the information on the number of simple operations that can be considered performed by each of them.

Since some machines may be able to perform more than one typology of simple operation, it is possible to instruct the equipment 25 to recognize these typologies, and count them separately.

For example, the equipment 25 may be programmed or programmable to contain simple reference information, each comprising the association of a reference absorption variation and the relative reference absorption time set during the setting. The equipment is then programmed to generate simple information of the same typologies as the reference ones, deriving it from the data detected during ordinary use, and to compare it with the reference data to recognize the typology of simple operations performed and calculate the number thereof.

In FIG. 4 a typical absorption spectrum is visible, it shows a period of time in which the absorbed current is greater. The variation in absorption is therefore an increase in absorbed current. The absorbed current may fluctuate during an operation, so it is possible for example to consider its average value, or it is possible to consider a simple operation completed when the absorption returns to stand-by values for a period longer than a reference threshold. The absorption period and the average value of absorbed voltage may be considered as reference parameters corresponding to a simple operation. The spectrum shown corresponds to the lifting of a vehicle lifting machine.

The equipment 25 may be programmed or programmable to contain complex reference information, corresponding to associations of simple reference operations. Each complex reference information identifies an association of different simple operations performed by one or more machines of the same center. These associations of simple operations are called complex operations. The equipment 25 is then programmed to generate complex information of the same typologies as the reference ones, deriving it from the data detected during ordinary use, and to compare it with the reference data to recognize the complex operations performed and calculate the number thereof.

For example, in the case of tire service centers, the association of a simple operation of lifting a vehicle and a simple tire disassembly operation is computed as a complex tire replacement operation. The association of a simple lifting operation and four simple tire disassembly operations in sequence is counted as a complex operation to replace all the tires of the same car.

The system is preferably able to associate a cost to each operation in order to easily be able to issues invoices, or simply matching checks with what is invoiced by the branches.

General Interpretation of Terms

In understanding the object of the present invention, the term “comprising” and its derivatives, as used herein, are intended as open-ended terms that specify the presence of declared characteristics, elements, components, groups, integers and/or steps, but do not exclude the presence of other undeclared characteristics, elements, components, groups, integers and/or steps. The above also applies to words that have similar meanings such as the terms “comprised”, “have” and their derivatives. Furthermore, the terms “part”, “section”, “portion”, “member” or “element” when used in the singular can have the double meaning of a single part or a plurality of parts. As used herein to describe the above executive embodiment(s), the following directional terms “forward”, “backward”, “above”, “under”, “vertical”, “horizontal”, “below” and “transverse”, as well as any other similar directional term, refers to the embodiment described in the operating position. Finally, terms of degree such as “mainly”, “about” and “approximately” as used herein are intended as a reasonable amount of deviation of the modified term such that the final result is not significantly changed.

While only selected embodiments have been chosen to illustrate the present invention, it will be apparent from this description to those skilled in the art that various modifications and variations can be made without departing from the scope of the invention as defined in the appended claims. For example, the size, shape, position or orientation of the various components can be modified as needed and/or desired. The components shown which are directly connected or in contact with each other can have intermediate structures arranged between them. The functions of one element can be performed by two and vice versa. The structures and functions of one embodiment can be adopted in another embodiment. All the advantages of a particular embodiment do not necessarily have to be present at the same time. Any characteristic that is original compared to the prior art, alone or in combination with other characteristics, should also be considered a separate description of further inventions by the applicant, including the structural and/or functional concepts embodied by such characteristics. Therefore, the foregoing descriptions of the embodiments according to the present invention are provided for illustrative purposes only and not for the purpose of limiting the invention as defined by the appended claims and their equivalents.

1-14. (canceled)

15. A monitored system for the provision of services comprising:
a plurality of electric absorption operating machines,
a monitoring equipment comprising:
at least one central processing and monitoring apparatus (20);
at least a plurality of devices for reading an electric absorption spectrum (15), each associated with an operating machine (10), and being in data communication with a central processing and monitoring apparatus (20);
wherein the equipment (25) is programmed to generate a plurality of simple information of a mutually different typology, where:
each typology of simple information corresponds to a simple typology of operation performed by a predetermined typology of operating machine;
each simple information corresponds to a single operation performed of said typology;
each simple information is recognized by the equipment based on all the following parameters:
the typology of operating machine,
variations in the absorption spectrum with respect to a stand-by absorption of the operating machine, wherein based on the duration of the absorption variation, each simple information includes the time of execution of the operation;
wherein the equipment is programmed to generate a plurality of complex information of a mutually different typology, wherein each typology corresponds to a predetermined concatenation of simple information that identifies a typology of complex operation formed by a plurality of single predetermined operations performed in a predetermined time succession within a predetermined time period, and each complex information generated identifies a complex operation performed by the plurality of operating machines;
wherein the central processing and monitoring apparatus is suitable for displaying the number of complex operations performed and/or a datum dependent thereon;
wherein the monitored system is capable of computing a number of complex operations of various typologies composed of a plurality of simple operations performed by machines of various typologies by using the reading of the variations in the electrical absorption of the machines associated with the absorption time and the typology of machine.

16. System according to claim 15, wherein the system is capable of comparing the absorption variation time with a reference time that is used as a threshold to establish whether the change is computable as a simple operation performed or not.

17. System according to claim 16, wherein the system is capable of considering a simple operation completed when the absorption returns to stand-by values for a period longer than a reference threshold.

18. System according to claim 15, wherein an absorbed current fluctuates during an operation, and the absorbed current average value is considered as reference parameter corresponding to a simple operation.

19. System according to claim 15, wherein
the typologies of simple predetermined operations recognized are selected from a list consisting of simple operations, Lifting of a vehicle lifting machine (commonly called “bridge”), lowering of a vehicle lifting machine, rotation of the plate of a machine for disassembling tires from rims, closing of the clamp of a balancing machine, opening of the clamp of a balancing machine, rotation of the tire on a balancing machine, lifting of an alignment machine, lowering of an alignment machine, actuation of cameras of an alignment machine; and
complex operations are selected from a group consisting of the following concatenations:

| Complex operations | Execution order |
|---|---|
| Tire replacement | C + C |
| Tire balancing | D + F + E |
| Tire repair | A + C + C + B |
| Tire reversal | A + 4(D + F + E) + B |
| Single wheel replacement | A + 2C + D + F + E + B |
| Complete wheel replacement | A + 8C + 4(D + F + E) + B |
| Alignment check | G + J + H |
| Alignment adjustment | G + J + G + J + H |

Wherein the execution order is determined according to the coding as follows:

| | |
|---|---|
| A | Lifting of a vehicle lifting machine (commonly called “bridge”) |
| B | Lowering of a vehicle lifting machine |
| C | Rotation of the plate of a machine for disassembling tires from |
| | rims |
| D | Closing of the clamp of a balancing machine |
| E | Opening of the clamp of a balancing machine |
| F | Rotation of the tire on a balancing machine |
| G | Lifting of an alignment machine |
| H | Lowering of an alignment machine |
| J | Actuation of cameras of an alignment machine. |

20. System according to claim 15, wherein an each of the at least a plurality of devices (15) is suitable for being interposed between the operating machine (10) and an electric power supply network (12), and each of the devices comprise:
at least one electrical supply socket (16) adapted to be connected to and disconnected from at least one electric machine (10) to be monitored and to electrically power it;
at least one connection (17) of the plurality of devices (15) to an electrical supply network (12) for drawing electric current;
at least one sensor (19) for measuring the electric current absorbed by the powered machine; and
data transmission means.

21. System according to claim 20, wherein the equipment is a kit (25) applicable to the machines (10) in public service provision centers (5) to be monitored where the devices (15) each comprise at least a socket and a plug, so as to be interposed between the sockets of the electrical power supply network (12) and the supply plugs of the machines (10), the devices (15) forming a switchboard (16).

22. System according to claim 15, further comprising a plurality of service provision centers (5) remote from each other and from the central processing and monitoring apparatus (20), each center (5) comprising a plurality of machines (10) and a relative plurality of spectrum reading devices (15) placed online with the central processing and monitoring apparatus, and each monitoring appraus is programmed to compute complex operations of each center, associating the simple operations with each other only if they belong to the same center.

23. System according to claim 22, wherein each center comprises at least one of the following typologies of machines (10), connected to said monitoring apparatus (20):
tire disassembly machine;
vehicle wheel alignment machine;
vehicle lifting machine; and
machine for checking and/or adjusting the convergence of vehicle wheels.

24. Monitoring equipment according to claim 23, wherein the monitoring equipment is distinct from the operating machines and can be connected thereto by means of a method for engaging the reading devices between the power supply sockets of the machines and the electrical supply sockets of the electric network.

25. Process for monitoring performed operations comprising the following steps:
arranging a plurality of electric absorption operating machines (10);
performing a plurality of operations in a random manner by means of said plurality of machines;
calculating the number of individual random operations performed by each machine divided by typologies of operations that can be performed by said machine, where the recognition of each operation is made based on the variations of the electric absorption spectrum of said machine and their duration time;
keeping track of the execution time of each simple operation;
recognizing the execution of various typologies of complex operations composed of a plurality of simple operations by comparison with predetermined reference concatenations composed of simple operations carried out in temporal succession in a predetermined period; and
calculating the number of complex operations performed.

26. Process according to claim 15, further comprising computing the number of complex operations composed of simple operations performed by a plurality of mutually different machines.

27. Process according to claim 25, further comprising centrally computing the number of complex operations performed in mutually remote service provision centers.

28. Process according to any of claim 25, wherein the process defines parameters of simple reference operations to be compared with the parameters detected to count the simple operations performed, where said parameters include an absorption variation and a time defined as follows:
performing a first predetermined number of individual operations by means of each machine,
defining a reference absorption variation for each operation based on the absorptions detected during said first predetermined number of operations;
setting a completion reference time for each typology of simple operation based on the times detected during said first predetermined number of operations.

29. Process according to claim 25, wherein each reference concatenation is defined as follows:
performing at least one complex test operation isolated from other operations;
storing the temporal succession in which its simple operations take place; and
setting a completion time for all its simple operations based on the time required to complete the complex test operation.

30. Process according to any one of claim 25, further comprising calculating a monetary value by associating a predetermined monetary value with each operation.

31. Process according to any one of claim 25, further comprising providing a plurality of assistance centers for vehicle tires, where the detected operations are selected from a group consisting of lifting of a vehicle lifting machine, lowering of a vehicle lifting machine, rotation of the plate of a machine for disassembling tires from rims, closing of the clamp of a balancing machine, opening of the clamp of a balancing machine, rotation of the tire on a balancing machine, lifting of an alignment machine, lowering of an alignment machine, and actuation of cameras of an alignment machine.
